(19) United States
(12) Patent Application Publication
(10) Pub. No.: US 2013/0037893 A1
(43) Pub. Date: Feb. 14, 2013

(54) SEMICONDUCTOR DEVICE

(71) Applicant: Seung Hyun LEE, Seoul (KR)

(72) Inventor: Seung Hyun LEE, Seoul (KR)

(21) Appl. No.: 13/336,050

(22) Filed: Dec. 23, 2011

(30) Foreign Application Priority Data
Aug. 9, 2011 (KR) 10-2011-0078970

(51) Int. Cl. H01L 29/82

(52) U.S. Cl. 257/421; 257/E29.323

(57) ABSTRACT

A semiconductor device includes a first free layer having a magnetic direction that changes according to a direction and an amount of a first current, a first tunnel insulating layer arranged on the first free layer, a pinned layer, arranged on the first tunnel insulating layer, having a magnetic direction set to a first direction, a second tunnel insulating layer arranged on the pinned layer, and a second free layer, arranged on the second tunnel insulating layer, having a magnetic direction that changes according to a direction and an amount of a second current.

### CROSS-REFERENCE(S) TO RELATED APPLICATIONS

The present application claims priority of Korean Patent Application No. 10-2011-0078970, filed on Aug. 9, 2011, which is incorporated herein by reference in its entirety.

### BACKGROUND OF THE INVENTION

The present invention relates to a magnetic tunnel junction device, and more particularly to a semiconductor device including a magnetic tunnel junction element device that stores multi-bit data.

A dynamic random access memory (DRAM), which is one of the most widely used semiconductor memory device, has such features as high operation speed and high integration. However, the DRAM is a volatile memory device that loses data when a power supply is off, and a refresh process is to be performed to maintain stored data. Meanwhile, a flash memory is a non-volatile memory device and may be highly integrated, but a flash memory has a slower operation speed than the DRAM. As compared with the DRAM and the flash memory, a semiconductor memory device including a magneto-resistance random memory device (MRAM) has such features as non-volatility, high operation speed, and high integration (scalability).

The MRAM device is a non-volatile memory device where data is stored by magnetic storage elements that have a different resistance according to a direction of a magnetic field between ferromagnetic plates. The magnetic storage element includes two ferromagnetic plates separated by an insulating layer. If polarities of the two ferromagnetic plates are parallel (the same), the magnetic storage element may have a relatively low resistance. Conversely, if polarities of the two ferromagnetic plates are opposite, the magnetic storage element has a maximum resistance. The MRAM device stores data based on a cell's resistance value that changes according to a magnetizing direction of ferromagnetic plates in the magnetic storage element. An example of a magnetic storage element is a Magnetic Tunnel Junction element.

The conventional MTJ includes a stacked structure of a first ferromagnetic layer, an insulating layer, and a second ferromagnetic layer. When electrons passing through a first ferromagnetic layer penetrate into an insulating layer serving as a tunneling barrier, an electron's probability of penetrating through the insulating layer is determined by the magnetic direction of the second ferromagnetic layer. If the two ferromagnetic layers have the same polarity (parallel magnetic direction), the amount of current tunneling through the insulating layer is relatively high. Conversely, if the two ferromagnetic layers have opposite magnetic directions, the amount of current tunneling the insulating layer is relatively low. For example, when the resistance based on the tunneling current is high, information stored in the MTJ is determined as a logic level “1” (or “0”). If the resistance is low, information stored in the MTJ is in a logic level “0” (or “1”). Herein, a first ferromagnetic layer of the two ferromagnetic layers is called a pinned layer because its polarity is set to particular value, but a second ferromagnetic layer is called a free layer because its polarity may be changed according to the amount of current penetrating through the insulating layer.

### SUMMARY OF THE INVENTION

An embodiment of the present invention is directed to a memory device including a magneto-resistive storage element that may store multi-bit data and has an features of scalability or density.

In accordance with an embodiment of the present invention, a semiconductor device includes a first free layer having a magnetic direction that changes according to a direction and an amount of a first current; a first tunnel insulating layer arranged on the first free layer; a pinned layer, arranged on the first tunnel insulating layer, having a magnetic direction set to a first direction; a second tunnel insulating layer arranged on the pinned layer; and a second free layer, arranged on the second tunnel insulating layer, having a magnetic direction that changes according to a direction and an amount of a second current.

In accordance with another embodiment of the present invention, a semiconductor device includes a first free layer having a magnetic direction that changes according to a direction and an amount of a first current; a first tunnel insulating layer arranged on the first free layer; a first pinned layer, arranged on the first tunnel insulating layer, having a magnetic direction set to a first direction; a second pinned layer, electronically coupled to the first pinned layer, having a magnetic direction set to a second direction that is an opposite direction of the first direction; a second tunnel insulating layer arranged on the second pinned layer; and a second free layer, arranged on the second tunnel insulating layer, having a magnetic direction that changes according to a direction and an amount of a second current.

### BRIEF DESCRIPTION OF THE DRAWINGS

FIG. 1 is a block diagram illustrating a magneto-resistive storage element in accordance with an embodiment of the present invention.

FIGS. 2A to 2D are block diagrams illustrating the operation of the magneto-resistive storage element shown in FIG. 1.

FIG. 3 is a block diagram illustrating one unit memory cell of a magneto-resistive random access memory including the magneto-resistive storage element shown in FIG. 1.

FIG. 4 is a block diagram illustrating a magneto-resistive storage element in accordance with another embodiment of the present invention.

FIGS. 5A to 5D are block diagrams illustrating the operation of the magneto-resistive storage element shown in FIG. 4.

FIG. 6 is a block diagram illustrating a magnetic force of the magneto-resistive storage element shown in FIG. 4.

FIG. 7 is a block diagram illustrating one unit memory cell of magneto-resistive random access memory including the magneto-resistive storage element shown in FIG. 4.

FIG. 8 is a block diagram illustrating a magneto-resistive storage element in accordance with another embodiment of the present invention.

FIG. 9 is a block diagram illustrating a magneto-resistive storage element in accordance with another embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

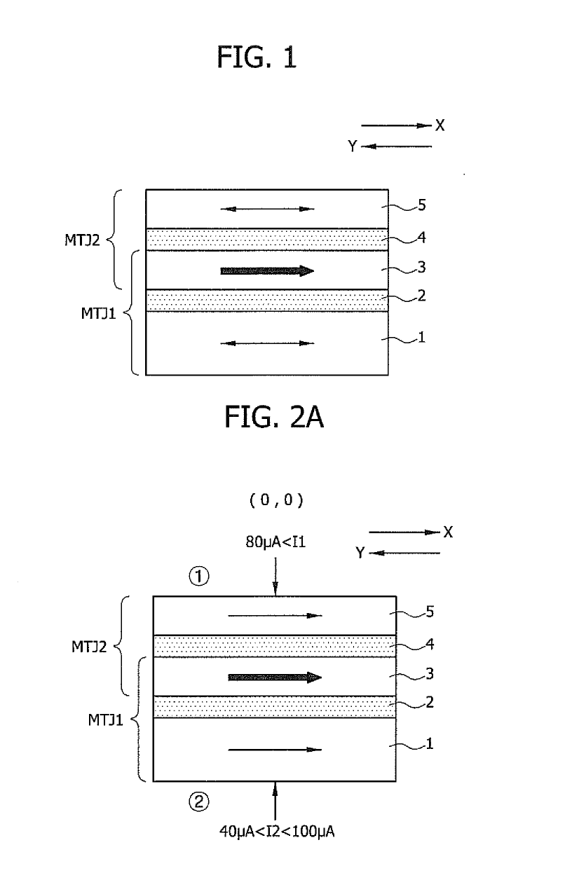

FIG. 1 is a block diagram illustrating a magneto-resistive storage element in accordance with an embodiment of the present invention.

As shown in FIG. 1, the magneto-resistive storage element includes a first free layer 1, a first tunnel insulating layer 2, a pinned layer 3, a second tunnel insulating layer 4, and a second free layer 5. More specifically, the first free layer 1, the first tunnel insulating layer 2, the pinned layer 3, the second tunnel insulating layer 4, and the second free layer 5 are stacked.

The first free layer 1, which has a magnetic direction changed according to direction of supplied current, may include at least one material marked by the chemical formula of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. The first tunnel insulating layer 2 may include MgO. Also, the first tunnel insulating layer 2 may be formed of a Group IV semiconductor material, or the first tunnel insulating layer 2 may be formed of a Group IV semiconductor material with Group III or V materials such as B, P, and As. The pinned layer 3, which has a polarity (i.e., magnetic direction) set to a first direction X, includes a first pinning plate and a first pinned plate. The pinned layer 3 fixes the magnetization direction of the first pinned plate. The pinning plate may include at least one material marked by the chemical formula of IrMn, PtMn, MnO, MnS, MnTe, MnF₂, FeF₂, FeCl₂, FeO, CoCl₂, CoO, NiCl₂, and NiO. Further, the pinned plate, which has a fixed polarity, may include at least one material marked by the chemical formula of Fe, Co, Ni, Gd, Dy, NiFe, CoFe, MnAs, MnBi, MnSb, CrO₂, MnOFe₂O₃, FeOFe₂O₃, NiOF₂O₃, CuOFe₂O₃, MgOFe₂O₃, EuO, and Y₃Fe₅O₁₂. The second tunnel insulating layer 4 may include MgO. Also, the second tunnel insulating layer 4 may be formed of a Group IV semiconductor material, or the second tunnel insulating layer 4 may be formed of a Group IV semiconductor material with Group III or V materials such as B, P, and As. The second free layer 5, which has a magnetic direction changed according to direction of supplied current, may include at least one material marked by the chemical formulae of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

Referring to FIG. 1, the magneto-resistive storage element includes two unit devices MTJ1 and MT2 commonly sharing the pinned layer 3. Here, the first unit device MTJ1 and the second unit device MTJ2 have different electric and magnetic properties. Thus, if a current having a designated amount flows into the first unit device MTJ1 and the second unit device MTJ2, which are connected to each other in series, the magnetic direction of the second free layer 5 in the second unit device MTJ2 may not be changed even though the magnetic direction of the first free layer 1 in the first unit device MTJ1 is changed. An operation of the magneto-resistive storage element is described as follows.

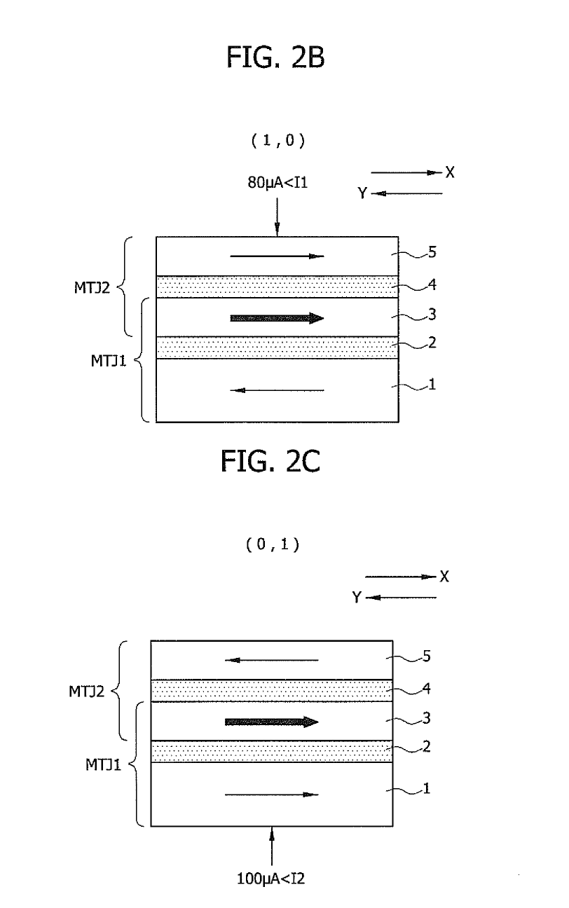

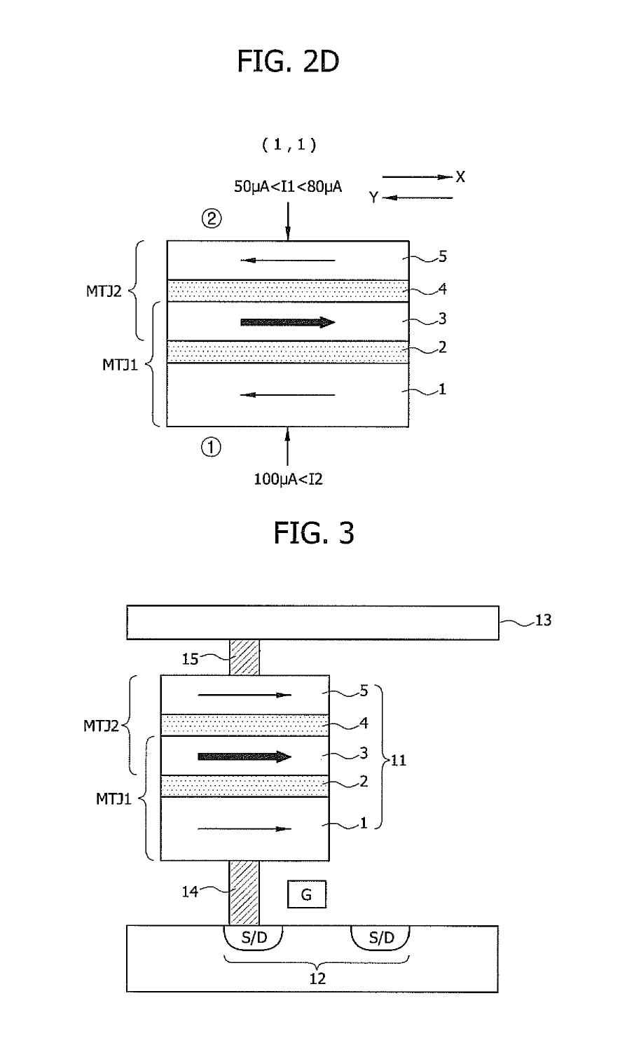

FIGS. 2A to 2D are block diagrams illustrating the operation of the magneto-resistive storage element shown in FIG. 1. The first unit device MTJ1 and the second unit device MTJ2 respectively have operational properties as shown in following Table 1.

TABLE 1

| | Logical Value | | | |
|---|---|---|---|---|
| | 0 (1^{st} direction) | 1 (2^{nd} direction) | 1□0 | 0□1 |
| | Resistance (kΩ) | | Current Amount (μA) | |
| MTJ1 | 2 | 10 | 40↑ | 50↓ |
| MTJ2 | 1 | 5 | 80↓ | 100↑ |

Referring to Table 1, the first unit device MTJ1 has a 2 kΩ resistance when a logical value is “0” and a 10 kΩ resistance when a logical value is “1”. To change the logical value of the first unit device from “1” to “0”, a 40 μA current is applied. Conversely, to change the logical value from “0” to “1”, a 50 μA current is applied.

The second unit device MTJ2 has a 1 kΩ resistance when a logical value is “0” and a 5 kΩ resistance when a logical value is “1”. To change the logical value of the second unit device from “1” to “0”, an 80 μA current is applied. Conversely, to change the logical value from “0” to “1”, a 100 μA current is applied.

40 μA for the first unit device MTJ1 is a current from the first free layer 1 to the second free layer 5, and 50 μA for the first unit device MTJ1 is a current from the second free layer 5 to the first free layer 1. Also, 80 μA for the second unit device MTJ2 is a current from the second free layer 5 to the first free layer 1, and 100 μA for the second unit device MTJ2 is a current from the first free layer 1 to the second free layer 5. 40 μA, 50 μA, 80 μA, and 100 μA are a current for changing the magnetic direction of the first and second free layers 1 and 5.

Additionally, if the first and second unit devices MTJ1 and MTJ2 have the logical value of “0”, the first and the second free layers 1 and 5 in the unit devices MTJ1 and MTJ2 have a magnetic direction of a first direction X. Otherwise, if the first and second unit devices MTJ1 and MTJ2 have the logical value of “1”, the first and the second free layers 1 and 5 in the unit devices MTJ1 and MTJ2 have a magnetic direction of a second direction Y. In these examples, the magnetic direction of the pinned layer 3 is set to the first direction X.

Referring to FIG. 2A, a current I1, which is more than 80 μA, is supplied from the second free layer 5 to the first free layer 1. Subsequently, another current I2, which is between 40 μA and 100 μA, is supplied from the first free layer 1 to the second free layer 5. Because the current I1 and the current I2 are respectively high enough to change the magnetic directions of the second and the first free layers 5 and 1, as shown in Table 1, the magnetic directions of the first and the second free layers 1 and 5 are changed to the first direction X. More specifically, the two unit devices MTJ1 and MTJ2 respectively store the logical value of “0”, and a total resistance of the magneto-resistive storage element is 3 kΩ. In a read operation, when the 3 kΩ resistance is detected, a magneto-resistive random access memory recognizes that the magneto-resistive storage element stores 2-bit data (0, 0).

Referring to FIG. 2B, a current I1, which is more than 80 μA, is supplied from the second free layer 5 to the first free layer 1. Because the 80 μA is a current high enough to change the magnetic direction of the second free layer 5 to the first direction X as shown in Table 1, the magnetic direction of the second free layer 5 is changed to the first direction X. Also, the current I1 may change the magnetic direction of the first free layer 1 to the second direction Y, as shown in Table 1, and the magnetic directions of the first free layer 1 is changed to the second direction Y. Thus, by supplying the current I1 to the magneto-resistive storage element, the first unit device MTJ1 stores the logical value of “1”, and the second unit device MTJ2 stores the logical value of “0”, and a total resistance of the magneto-resistive storage element is 11 kΩ. In a read operation, when the 11 kΩ resistance is detected, a magneto-resistive random access memory recognizes that the magneto-resistive storage element stores another 2-bit data (1, 0).

Referring to FIG. 2C, a current I2, which is more than 100 μA, is supplied from the first free layer 1 to the second free layer 5. Because the current I2 is high enough to change the magnetic direction of the first free layer 1 to a first direction X, as shown in Table 1, the magnetic direction of the first free layer 1 is changed to the first direction X. Also, the current I2 may change the magnetic direction of the second free layer to the second direction Y, as shown in Table 2, and the magnetic direction of the second free layer 5 is changed to the second direction Y. Thus, by supplying the current I2 to the magneto-resistive storage element, the first unit device MTJ1 stores the logical value of “0”, and the second unit device MTJ2 stores the logical value of “1”, and a total resistance of the magneto-resistive storage element is 7 kΩ. If the 7 kΩ resistance is detected in a read operation, a magneto-resistive random access memory recognizes that the magneto-resistive storage element stores another 2-bit data (0, 1).

Referring to FIG. 2D, a current I1, which is more than 100 μA, is supplied from the first free layer 1 to the second free layer 5. Subsequently, another current I2, which is between 50 μA and 80 μA, is supplied from the second free layer 5 to the first free layer 1. Because the current I1 and the current I2 are respectively high enough to change the magnetic directions of the first and the second free layers 1 and 5 to the second direction Y, as shown in Table 1, the magnetic directions of the first and the second free layers 1 and 5 are changed to the second direction Y. More specifically, the first and the second unit device MTJ1 and MTJ2 respectively store the logical value of “1”, and a total resistance of the magneto-resistive storage element is 15 kΩ. If the 15162 resistance is detected in a read operation, a magneto-resistive random access memory recognizes that the magneto-resistive storage element stores another 2-bit data (1, 1).

In the magneto-resistive storage element of the embodiment, two unit devices MTJ1 and MTJ2 that have different electronic and magnetic properties are connected in series. By changing the magnetic direction of the two unit devices MTJ1 and MTJ2, the magneto-resistive storage element has four different resistance values. Thus, the magneto-resistive random access memory may read and write 2-bit data in a single magneto-resistive storage element. Because the unit devices MTJ1 and MTJ2 share the pinned layer 3, the magneto-resistive random access memory has such features as lower cost and higher scalability as compared with a conventional magneto-resistive random access memory.

FIG. 3 is a block diagram illustrating one unit memory cell of the magneto-resistive random access memory in accordance with another embodiment of the present invention.

As shown in FIG. 3, the single unit memory cell of the magneto-resistive random access memory includes a single magneto-resistance storage element 11, a single switching device 12, and a single bit line 13.

The single magneto-resistance storage element 11 includes two unit devices MTJ1 and MTJ2 serially connected to each other to store 2-bit data. A magnetic direction of each unit device MTJ1 and MTJ2 is changed according to supplied currents that have different amounts of current and directions so that the magneto-resistance storage element 11 has four different resistance values. Operation of the magneto-resistance storage element 11 is similar to that of the magneto-resistive storage element shown in FIGS. 1 and 2a to 2d.

The switching device 12, which is connected to the magneto-resistance storage element, serves to select the magneto-resistance storage element 11 in response to an address signal inputted from an external device and to supply currents to the magneto-resistance storage element 11 to change the magnetic directions of the free layers 1 and 5 included in the magneto-resistive storage element 11 to the second direction Y or the first direction X. The switching device 12 includes a transistor having a source/drain, which is electronically coupled to the first free layer 1 through a contact plug 14. The address signal is a signal inputted for reading stored data from or writing data to the magneto-resistance storage element 11.

The bit line 13 serves to supply currents to the magneto-resistance storage element 11 to change the magnetic directions of the free layers 1 and 5 to the first direction X or the second direction Y. The bit line 13 includes a wire configured to deliver current and is coupled to the second free layer 5 through a contact plug 15.

A single memory cell may store 2-bit data because the single magneto-resistance storage element 11 includes two unit devices MTJ1 and MTJ2. To store 2-bit data, the conventional MRAM needs two memory cells including two switching devices and two magneto-resistance storage elements. However, the MRAM device according to the embodiment of the present invention may store 2-bit data in the single memory cell that has one switching device and one magneto-resistance storage element. Thus, assuming that the 2-bit data is stored, the magneto-resistance memory device of the exemplary embodiments may be scaled down by an area occupied by one switching device.

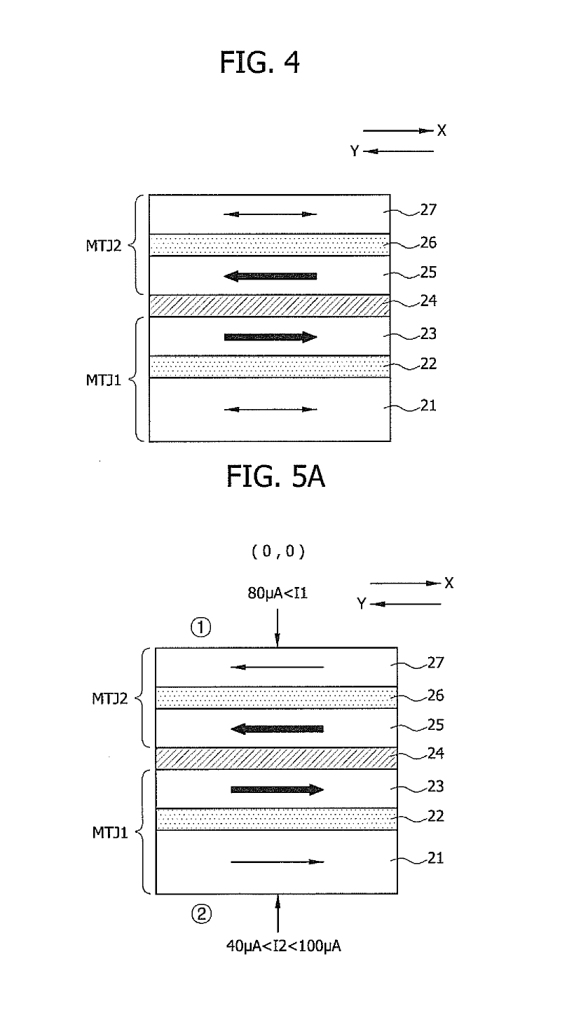

FIG. 4 is a block diagram illustrating a magneto-resistive storage element in accordance with another embodiment of the present invention.

As shown in FIG. 4, the magneto-resistive storage element includes a first free layer 21, a first tunnel insulating layer 22, a first pinned layer 23, a reversed magnetization layer 24, a second pinned layer 25, a second tunnel insulating layer 26, and a second free layer 27. More specifically, the first free layer 21, the first tunnel insulating layer 22, the first pinned layer 23, the reversed magnetization layer 24, the second pinned layer 25, the second tunnel insulating layer 26, and the second free layer 27 are stacked.

The first free layer 21, which has a magnetic direction changed according to direction of supplied current, may include at least one material marked by the chemical formula of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. The first tunnel insulating layer 22 may include MgO. Also, the first tunnel insulating layer 22 may be formed of a Group IV semiconductor material, or the first tunnel insulating layer 22 may be formed of a Group IV semiconductor material with Group III or V materials such as B, P, and As. The first pinned layer 23, which has a polarity (i.e., magnetic direction) set to a first direction X includes a first pinning plate and a first pinned plate. The first pinned layer 23 fixes the magnetization direction of the first pinned plate. The pinning plate may include at least one material marked by the chemical formula of IrMn, PtMn, MnO, MnS, MnTe, MnF₂, FeF₂, FeCl₂, FeO, CoCl₂, CoO, NiCl₂, and NiO. Further, the pinned plate having a fixed polarity may include at least one material marked by the chemical formula of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. The reversed magnetization layer 24, which is arranged between the first pinned layer 23 and the second pinned layer 25, serves to fix the magnetic direction of the first pinned layer 23 to the first direction X, and the magnetic direction of the second pinned layer 25 is set to the second direction Y. The second pinned layer 25 has the magnetic direction set to the second direction Y. The second pinned layer 25 may include at least one material marked by the chemical formula of IrMn, PtMn, MnO, MnS, MnTe, MnF₂, FeF₂, FeCl₂, FeO, CoCl₂, CoO, NiCl₂, NiO, Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. The second tunnel insulating layer 26 may include MgO. Also, the second tunnel insulating layer 26 may be formed of a Group IV semiconductor material, or the second tunnel insulating layer 26 may be formed of a Group IV semiconductor material with Group III or V materials such as B, P, and As. The second free layer 27, which has a magnetic direction changed according to direction of supplied current, may include at least one material marked by the chemical formula of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

Referring to FIG. 4, the magneto-resistive storage element includes two unit devices MTJ1 and MT2. Here, the first unit device MTJ1 and the second unit device MTJ2 respectively have different electric and magnetic properties. Thus, if a current having a designated amount flows into the first unit device MTJ1 and the second unit device MTJ2, the magnetic direction of the second free layer 5 in the second unit device MTJ2 is not changed even though the magnetic direction of the first free layer 1 in the first unit device MTJ1 may be changed. Operation of the magneto-resistive storage element is described as follows.

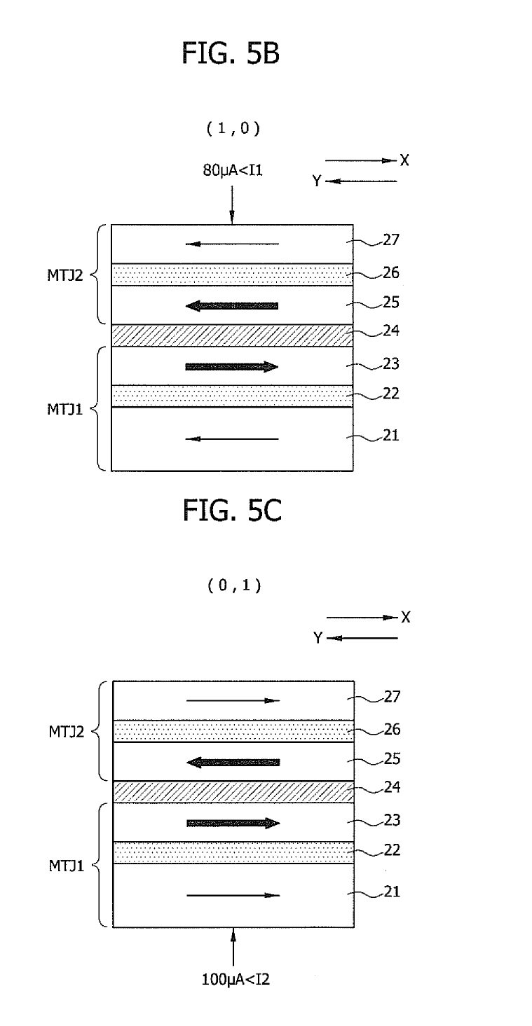

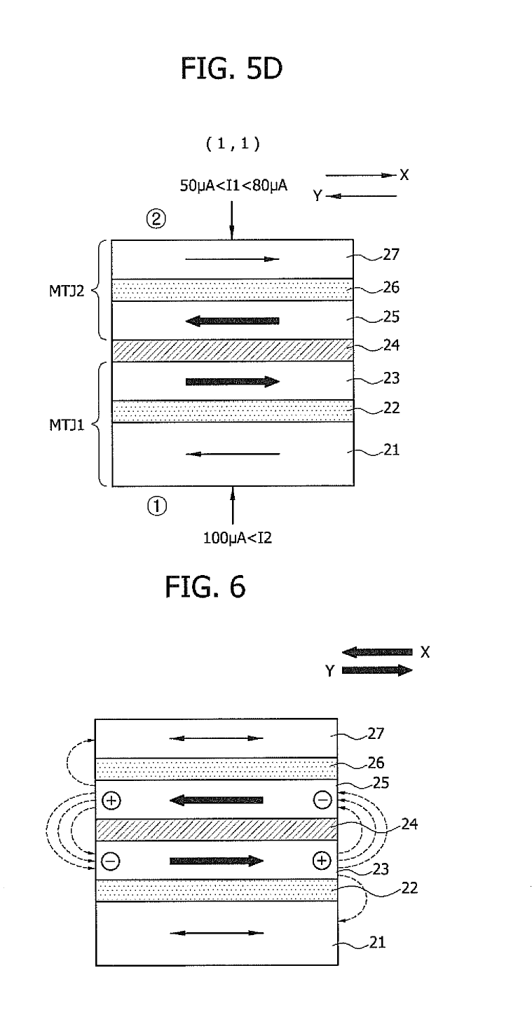

FIGS. 5A to 5D are block diagrams illustrating an operation of the magneto-resistive storage element shown in FIG. 4. The first unit device MTJ1 and the second unit device MTJ2 respectively have operational properties as shown in following Table 2.

TABLE 2

| | Logical Value | | | |
|---|---|---|---|---|
| | 0 (1stdirection) | 1 (2nddirection) | 1□0 | 0□1 |
| | Resistance (kΩ) | | Current Amount (μA) | |
| MTJ1 | 2 | 10 | 40↑ | 50↓ |
| MTJ2 | 1 | 5 | 80↓ | 100↑ |

Referring to Table 1, the first unit device MTJ1 has a 2 kΩ resistance when a logical value is “0” and a 10 kΩ resistance when a logical value is “1”. To change the logical value of the first unit device from “1” to “0”, a 40 μA current is applied. Conversely, to change the logical value from “0” to “1”, a 50 μA current is required.

The second unit device MTJ2 has a 1 kΩ resistance when a logical value is “0” and a 5 kΩ resistance when a logical value is “1”. To change the logical value of the second unit device from “1” to “0”, an 80 μA current is required. Conversely, to change the logical value from “0” to “1”, a 100 μA current is required.

40 μA for the first unit device MTJ1 is a current from the first free layer 1 to the second free layer 5, and 50 μA for the first unit device MTJ1 is a current from the second free layer 5 to the first free layer 1. Also, 80 μA for the second unit device MTJ2 is a current from the second free layer 5 to the first free layer 1, and 100 μA for the second unit device MTJ2 is a current from the first free layer 1 to the second free layer 5. 40 μA, 50 μA, 80 μA, and 100 μA are a limited current for changing the magnetic direction of the first and second free layers 1 and 5.

Additionally, if the first and second unit devices MTJ1 and MTJ2 have the logical value of “0”, when the first pinned layer 23 is set to the first direction X and the second pinned layer 25 is set to the second direction Y, the first free layer 21 has the polarity of the first direction X and the magnetic direction of second free layer 27 is set to the second direction Y. More specifically, when two layers, i.e., the first pinned layer 23 and the first free layer 21, of the first unit device MTJ1 and two layers, i.e., the second pinned layer 25 and the second free layer 27, of the second device MTJ2 have respectively the same magnetic directions, the first and the second unit devices MTJ1 and MTJ2 store a logical value of “0”. Otherwise, if the first and second unit devices MTJ1 and MTJ2 have the logical value of “1”, each two layers in the unit devices MTJ1 and MTJ2 have different magnetic directions.

Referring to FIG. 5A, a current I1, which is more than 80 μA, is supplied from the second free layer 27 to the first free layer 21. Subsequently, another current I2, which is between 40 μA and 100 μA, is supplied from the first free layer 21 to the second free layer 27. Because the current I1 may change the magnetic direction of the second free layer 27, as shown in Table 2, the second free layer 27 is set to the second direction Y. Because the current I2 is high enough to change magnetic direction of the first free layer 21, as shown in Table 2, the magnetic direction of the first free layer 21 is changed to the first direction X. More specifically, the two unit devices MTJ1 and MTJ2 respectively store the logical value of “0”, and a total resistance of the magneto-resistive storage element is 3 kΩ. In a read operation, when the 3 kΩ resistance is detected, a magneto-resistive random access memory recognizes that the magneto-resistive storage element stores 2-bit data (0, 0).

Referring to FIG. 5B, a current I1, which is more than 80 μA, is supplied from the first free layer 21 to the second free layer 27. Because the current I1 is high enough to change the magnetic directions of the first and the second free layers 21 and 27 to the second direction Y, as shown in Table 2, the magnetic directions of the first and the second free layers 21 and 27 are changed to the second direction Y. Thus, the first unit device MTJ1 stores the logical value of “1”, and the second unit device MTJ2 stores the logical value of “0”, and a total resistance of the magneto-resistive storage element is 11 kΩ. In a read operation, when the 11 kΩ resistance is detected, a magneto-resistive random access memory recognizes that the magneto-resistive storage element stores another 2-bit data (1, 0).

Referring to FIG. 5C, a current I2, which is more than 100 μA, is supplied from the first free layer 21 to the second free layer 27. Because the current I2 is high enough to change the magnetic directions of the first and the second free layers 21 and 27 to the first direction X, as shown in Table 2, the magnetic directions of the first and the second free layers 21 and 27 are changed to the first direction X. More specifically, the first unit device MTJ1 stores the logical value of “0”, and the second unit device MTJ2 stores the logical value of “1”, and a total resistance of the magneto-resistive storage element is 7 kΩ. When the 7 kΩ resistance is detected in a read operation, a magneto-resistive random access memory recognizes that the magneto-resistive storage element stores another 2-bit data (0, 1).

Referring to FIG. 5D, a current I1, which is more than 100 μA, is supplied from the first free layer 21 to the second free layer 27. Subsequently, another current I2, which is between 50 μA and 80 μA, is supplied from the second free layer 27 into the first free layer 21. Because the current I1 is high enough to change the magnetic direction of the second free layer 27 to the first direction X, as shown in Table 2, the second free layer 27 is set to the first direction X. Also, the current I2 may change the magnetic direction of the first free layer 21 to the second direction Y, as shown in Table 2, and the magnetic direction of the first free layer 21 is changed to the second direction Y. More specifically, the first and second unit device MTJ1 and MTJ2 respectively store the logical value of “1”, and a total resistance of the magneto-resistive storage element is 15 kΩ. If the 15 kΩ resistance is detected in a read operation, a magneto-resistive random access memory recognizes that the magneto-resistive storage element stores another 2-bit data (1, 1).

In the magneto-resistive storage element of the embodiment, two unit devices MTJ1 and MTJ2 that have different electronic and magnetic properties are connected in series. By changing the magnetic direction of the two unit devices MTJ1 and MTJ2, the magneto-resistive storage element has four different resistance values. In the exemplary embodiment, each of the pinned layers 23 and 25 in the two unit device MTJ1 and MTJ2 has a different magnetic direction from each other, though the pinned layers 23 and 25 in the two unit device MTJ1 and MTJ2 are adjoined to each other. If two nearby pinned layers 23 and 25 have opposite magnetic directions, changing magnetic directions of the first and the second free layers 21 and 27 by a magnetic field of the two pinned layers 23 and 25 may be reduced. In operations for changing magnetic directions of the first and the second free layers 21 and 27, noise or interference from the magnetic field of the two pinned layers 23 and 25 is decreased by the following description.

FIG. 6 is a block diagram illustrating a magnetic force of the magneto-resistive storage element shown in FIG. 4.

As shown in FIG. 6, most of the magnetic force of the first pinned layer 23 is applied in direction of the second pinned layer 25, and most of the magnetic force of the second pinned layer 25 is applied in direction of the first pinned layer 25. In the exemplary embodiment, the first and the second pinned layers are similar to a magnet bar including two different polarities (‘+’ and ‘−’) to generate a magnetic force from a positive one ‘+’ to a negative one ‘−’. According to the magnetic direction, the magnetic forces of the first and the second pinned layers 23 and 25 affect each other rather than the first and the second free layers 21 and 27. Thus, in the operations of the magneto-resistive storage element, noise or interference to the first and the second free layer 21 and 27 may be reduced.

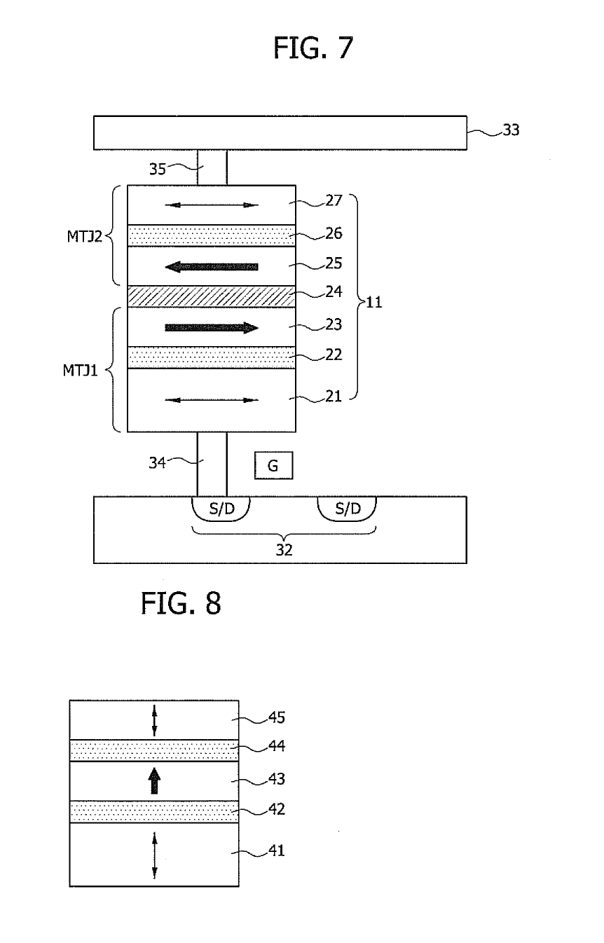

FIG. 7 is a block diagram describing one unit memory cell of magneto-resistive random access memory including the magneto-resistive storage element shown in FIG. 4.

As shown in FIG. 7, the single unit memory cell of the magneto-resistive random access memory includes a single magneto-resistance storage element 31, a single switching device 32, and a single bit line 33.

The single magneto-resistance storage element 31 includes two unit devices MTJ1 and MTJ2 serially connected to each other to store 2-bit data. A magnetic direction of each unit device MTJ1 and MTJ2 is changed according to supplied currents that have different amounts of current and directions so that the magneto-resistance storage element 31 has four different resistance values. Operation of the magneto-resistance storage element 31 is similar to that of the magneto-resistive storage element shown in FIGS. 4 and 5a to 5d.

The switching device 32, which is connected to the magneto-resistance storage element, serves to select the magneto-resistance storage element 31 in response to an address signal inputted from an external device, and to supply currents to the magneto-resistance storage element 31 to change the magnetic directions of the free layers 21 and 27 included in the magneto-resistive storage element 31 to the second direction Y or the first direction X. The switching device 32 includes a transistor having a source/drain, which is electronically coupled to the first free layer 21 through a contact plug 34. The address signal is a signal inputted for reading stored data from or writing data to the magneto-resistance storage element 31.

The bit line 33 serves to supply currents to the magneto-resistance storage element 31 to change the magnetic directions of the free layers 21 and 27 to the first direction X or the second direction Y. The bit line 33 includes a wire configured to deliver current and is coupled to the second free layer 27 through a contact plug 35.

A single memory cell may store 2-bit data because the single magneto-resistance storage element 11 includes two unit devices MTJ1 and MTJ2. To store 2-bit data, the conventional MRAM needs two memory cells including two switching devices and two magneto-resistance storage elements. However, the MRAM device according to the embodiment of the present invention may store 2-bit data in the single memory cell that has one switching device and one magneto-resistance storage element. Thus, assuming that the 2-bit data is stored, the magneto-resistance memory device of the exemplary embodiments may be scaled down by an area occupied by one switching device.

FIG. 8 is a block diagram illustrating a magneto-resistive storage element in accordance with another embodiment of the present invention.

As shown in FIG. 8, the magneto-resistive storage element has a similar structure as the magneto-resistive storage element shown in FIG. 1, but a first free layer 41, a pinned layer 43, and a second free layer 45 have vertical magnetic directions. If the magnetic directions of the first free layer 41, the pinned layer 43 and the second free layer 45 are formed vertically, plan areas of the magnetic directions of the first free layer 41, the pinned layer 43, and the second free layer 45 may be reduced. The magneto-resistive storage element also includes tunnel insulating layers 42 and 44. Generally, a magnetic direction of magnetic layer is determined by its profile. If the profile of magnetic layer is thin but large, the magnetic direction is formed in a longer direction, i.e., horizontally not vertically. Thus, the magnetic layers should have large plan area for stable operation. However, in an embodiment where magnetic layers having a vertical magnetic direction, the magnetic direction is determined by an included material, not a profile. Thus, if the magnetic layer has a vertical magnetic direction, stable operation may be performed even if the plan area of the magnetic layer becomes smaller.

Thus, if the first free layer 41, the pinned layer 43, and the second free layer 45 have a vertical magnetic direction, a plan area of the magneto-resistive storage element may be reduced. Operations of the magneto-resistive storage element are same to those of the magneto-resistive storage element shown in FIGS. 1 and 2a to 2d, and descriptions about the operations are omitted.

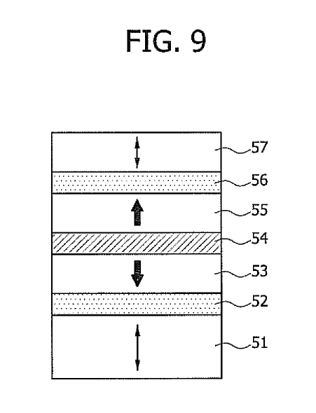

FIG. 9 is a block diagram illustrating a magneto-resistive storage element in accordance with another embodiment of the present invention.

As shown in FIG. 9, the magneto-resistive storage element has a similar structure as the magneto-resistive storage element shown in FIG. 4, but a first free layer 51, a first pinned layer 53, a second pinned layer 55, and a second free layer 57 have vertical magnetic directions. If the magnetic directions of the first free layer 51, the first pinned layer 53, the second pinned layer 55, and the second free layer 57 are formed vertically, plan areas of the first free layer 51, the first pinned layer 53, the second pinned layer 55, and the second free layer 57 may be smaller than the first free layer 21, the first pinned layer 23, the second pinned layer 25, and the second free layer 27 shown in FIG. 4. The magneto-resistive storage element includes tunnel insulating layers 42 and 44 and a reserved magnetization layer 54 including a metal layer such as a ruthenium (Ru).

If the first free layer 51, the first pinned layer 53, the second pinned layer 55, and the second free layer 57 have a vertical magnetic direction, a plan area of the magneto-resistive storage element is reduced. Operations of the magneto-resistive storage element are same to those of the magneto-resistive storage element shown in FIGS. 4 and 5a to 5d, and descriptions about the operations are omitted.

As discussed earlier, in accordance with exemplary embodiments of the present invention, the magneto-resistance memory device includes a memory cell having one magneto-resistance storage element configured to store 2-bit data and one switching device. To store 2-bit data, the conventional MRAM needs two memory cells including two switching devices and two magneto-resistance storage elements. However, the MRAM device according to the embodiments of the present invention may store 2-bit data in a single memory cell having a structure of one switching devices and two magneto-resistance storage elements. Thus, assuming that the 2-bit data is stored, the magneto-resistance memory device of the embodiments may be scaled down by an area occupied by one switching device.

Further, a single memory cell may store more than 2-bit data. To store more than 2-bit data, the single memory cell includes more than two magneto-resistance storage elements according to the exemplary embodiments of the present invention.

In embodiments of the present invention, the magneto-resistance memory device includes a plurality of memory cells, each including one magneto-resistance storage element configured to store a multi-bit data and one switching device. Thus, assuming that the same N-bit data is stored in the conventional MRAM and the magneto-resistance memory device according to the present invention, the magneto-resistance memory device may reduce a plan area occupied by (N−1) number of switching devices.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a first free layer having a magnetic direction that changes according to a direction and an amount of a first current;
a first tunnel insulating layer arranged on the first free layer;
a pinned layer, arranged on the first tunnel insulating layer, having a magnetic direction set to a first direction;
a second tunnel insulating layer arranged on the pinned layer; and
a second free layer, arranged on the second tunnel insulating layer, having a magnetic direction that changes according to a direction and an amount of a second current.

2. The semiconductor device as recited in claim 1, wherein the magnetic direction of the first free layer is changed according to a first amount of the first current supplied from the second free layer to the first free layer and a second amount of the first current supplied from the first free layer to the second free layer, and the magnetic direction of the second free layer is changed according to a first amount of the second current supplied from the second free layer to the first free layer and a second amount of the second current supplied from the first free layer to the second free layer.

3. The semiconductor device as recited in claim 2, wherein, if an amount of an operating current supplied from the second free layer to the first free layer is equal to or larger than both of the second amount of the first current and the first amount of the second current, the magnetic direction of the second free layer is changed to the first direction and the magnetic direction of the first free layer is changed to a second direction that is different from the first direction.

4. The semiconductor device as recited in claim 2, wherein, if an amount of a first operating current supplied from the second free layer to the first free layer is equal to or larger than both of the second amount of the first current and the first amount of the second current, and an amount of a second operating current supplied from the first free layer to the second free layer is between the first amount of the first current and the second amount of the second current,
the magnetic direction of the first free layer and second free layer is changed to the first direction.

5. The semiconductor device as recited in claim 2, wherein, if an amount of an operating current supplied from the first free layer to the second free layer is equal to or larger than both of the first amount of the first current and the second amount of the second current, the magnetic direction of the first free layer is changed to the first direction and the magnetic direction of the second free layer is changed to a second direction that is different from the first direction.

6. The semiconductor device as recited in claim 2, wherein, if an amount of a first operating current supplied from the first free layer to the second free layer is equal to or larger than both of the first amount of the first current and the second amount of the second current, and an amount of a second operating current supplied from the second free layer to the first free layer is between the second amount of the first current and the first amount of the second current,
the magnetic direction of the first free layer and second free layer is changed to a second direction that is different from the first direction.

7. The semiconductor device as recited in claim 1, wherein, the magnetic direction of the first free layer and second free layer are parallel or perpendicular.

8. A semiconductor device, comprising:
a first free layer having a magnetic direction that changes according to a direction and an amount of a first current;
a first tunnel insulating layer arranged on the first free layer;
a first pinned layer, arranged on the first tunnel insulating layer, having a magnetic direction set to a first direction;
a second pinned layer, electronically coupled to the first pinned layer, having a magnetic direction set to a second direction that is an opposite direction of the first direction;
a second tunnel insulating layer arranged on the second pinned layer; and
a second free layer, arranged on the second tunnel insulating layer, having a magnetic direction that changes according to a direction and an amount of a second current.

9. The semiconductor device as recited in claim 8, wherein the magnetic direction of the first free layer is changed according to a first amount of the first current supplied from the second free layer to the first free layer and a second amount of the first current supplied from the first free layer to the second free layer, and the magnetic direction of the second free layer is changed according to a first amount of the second current supplied from the second free layer to the first free layer and a second amount of the second current supplied from the first free layer to the second free layer.

10. The semiconductor device as recited in claim 9, wherein, if an amount of an operating current supplied from the second free layer to the first free layer is equal to or larger than both of the second amount of the first current and the first amount of the second current, the magnetic direction of the second free layer is changed to the first direction and the magnetic direction of the first free layer is changed to a second direction that is different from the first direction.

11. The semiconductor device as recited in claim 9, wherein, if an amount of a first operating current supplied from the second free layer to the first free layer is equal to or larger than both of the second amount of the first current and the first amount of the second current, and an amount of a second operating current supplied from the first free layer to the second free layer is between the first amount of the first current and the second amount of the second amount,
the magnetic direction of the first free layer and second free layer is changed to the first direction.

12. The semiconductor device as recited in claim 9, wherein, if an amount of an operating current supplied from the first free layer to the second free layer is equal to or larger than both of the first amount of the first current and the second amount of the second current, the magnetic direction of the first free layer is changed to the first direction and the magnetic direction of the second free layer is changed to a second direction which is different from the first direction.

13. The semiconductor device as recited in claim 9, wherein, if an amount of a first operating current supplied from the first free layer to the second free layer is equal to or larger than both of the first amount of the first current and the second amount of the second current, and an amount of a second operating current supplied from the second free layer to the first free layer is between the second amount of the first current and the first amount of the second current,
the magnetic direction of the first free layer and second free layer is changed to a second direction which is different from the first direction.

14. The semiconductor device as recited in claim 9, wherein, the magnetic directions of the first free layer and second free layer are parallel or perpendicular.

15. The semiconductor device as recited in claim 8, further comprising a reversed magnetization layer, arranged in between the first pinned layer and the second pinned layer, configured to fix the magnetic direction of the first pinned layer in an opposite magnetic direction as the magnetic direction of the second pinned layer.

16. The semiconductor device as recited in claim 15, wherein the reversed magnetization layer includes ruthenium (Ru).
